(19) United States
(12) Patent Application Publication
(10) Pub. No.: US 2021/0398800 A1
(43) Pub. Date: Dec. 23, 2021

(54) METHOD FOR PREPARING A NANOSHEET AND A MULTILAYER STRUCTURE

(71) Applicant: City University of Hong Kong, Kowloon (HK)

(72) Inventors: Yong Yang, Kowloon (HK); Tianyu Wang, Kowloon (HK); Jingyang Zhang, Kowloon (HK); Quanfeng He, Kowloon (HK)

(21) Appl. No.: 16/903,572

(22) Filed: Jun. 17, 2020

(51) Int. Cl. H01L 21/02

(52) U.S. Cl. CPC H01L 21/0259; H01L 21/02186; H01L 21/02282; H01L 21/02266

(57) ABSTRACT

The present invention relates to a method for preparing a nanosheet including the steps of: depositing a solution onto a substrate to form a first layer, wherein the substrate is rotatable relative to the depositing solution; depositing and condensing target material onto the first layer to form a second layer; and separating the second layer from the first layer and the substrate to form a nanosheet. Also disclosed a multilayer structure including: a substrate; a first layer arranged to deposit onto the substrate, wherein the substrate is rotatable relative to the depositing of the first layer; and a second layer arranged to deposit onto the first layer and separable from the first layer to form a nanosheet.

### TECHNICAL FIELD

The present invention relates to a method for preparing nanosheet and a multilayer structure, specifically, although not exclusively, to a method for preparing a large-area nanosheet and a multilayer structure from which a large-area nanosheet is formed.

### BACKGROUND

A nanosheet is a two-dimensional nanostructure with an ultrathin thickness in a scale ranging from 1 to 100 nm. Among various types of nanosheets, metal and ceramic nanosheets as a special kind of material, has drawn tremendous interests owing to their impressing physical properties and the related potential applications.

However, the limited availability of synthesis methods remains one of the narrowest bottlenecks and huge obstacles for fabricating more complicated nanosheets. Thus, more advanced synthesis processes are still highly sought in order to take full advantages of nanosheets in a wide range of practical applications such as electronics e.g. sensing and imaging techniques etc. and chemical reactions.

### BRIEF DESCRIPTION OF THE DRAWINGS

Embodiments of the present invention will now be described, by way of example, with reference to the accompanying drawings in which:

FIG. 1a is a block diagram showing the process flow of a method for preparing a nanosheet in accordance with one embodiment of the present invention;

FIG. 1b is a schematic diagram showing the multilayer structure in accordance with one embodiment of the present invention;

FIG. 2a is a schematic description for the developed synthesis method in this invention;

FIG. 2b is a schematic description for the developed synthesis method in this invention;

FIG. 2c is a schematic description for the developed synthesis method in this invention;

FIG. 3 provides (a) a a photo of the as-prepared PVA-glass plate stated in step 1, and (b) a photo of the PVA-glass plate after Ti film deposition (correspond to step 2);

FIG. 4 provides (a) a photo of the peeled off Ti nanosheets as stated in step 3, and (b) a photo of the peeled off Ti nanosheets as stated in step 3;

FIG. 5 depicts Ti nanosheets exfoliated and collected from 4 glass slides (400 cm²);

FIG. 6 provides (a) an optical image of the Ti nanosheet placed on 300-mesh copper grid, (b) an optical image of the Ti nanosheet placed on Si wafer, (c) a transmission electron microscope (TEM) image of the fabricated Ti nanosheet (the inset is the corresponding diffraction pattern), and (d) a high resolution TEM image of the fabricated Ti nanosheet (the inset is the corresponding fast Fourier transform (FFT)) image;

FIG. 7 provides (a) is an optical image of the FeCoNiCrNb nanosheet placed on 300-mesh copper grid, (b) an optical image of the FeCoNiCrNb nanosheet placed on Si wafer, (c) a TEM image of the fabricated FeCoNiCrNb nanosheet (the inset is the corresponding diffraction pattern), and (d) a high resolution TEM image of the fabricated FeCoNiCrNb nanosheet (the inset is the corresponding FFT image);

FIG. 8 provides (a) an optical image of the TiO₂ nanosheet placed on 300-mesh copper grid, (b) an optical image of the TiO₂ nanosheet placed on Si wafer, (c) a TEM image of the fabricated TiO₂ nanosheet (the inset is the corresponding diffraction pattern), and (d) a high resolution TEM image of the fabricated TiO₂ nanosheet (the inset is the corresponding FFT image); and

FIG. 9 provides (a) an optical image of the SiC nanosheet placed on 300-mesh copper grid, (b) an optical image of the SiC nanosheet placed on Si wafer, (c) a TEM image of the fabricated SiC nanosheet (the inset is the corresponding diffraction pattern), and (d) a high resolution TEM image of the fabricated SiC nanosheet (the inset is the corresponding FFT image).

### SUMMARY OF THE INVENTION

In accordance with the first aspect of the present invention, there is provided a method for preparing a nanosheet comprising the steps of: A) depositing a solution onto a substrate to form a first layer, wherein the substrate is rotatable relative to the depositing solution; B) depositing and condensing target material onto the first layer to form a second layer; and C) separating the second layer from the first layer and the substrate to form a nanosheet.

In an embodiment of the first aspect, step A) includes spin-coating the solution uniformly onto the substrate to form the first layer.

In an embodiment of the first aspect, step A) includes step A1) of rotating the substrate relative to the depositing solution, thereby uniformly distributing the solution onto the substrate.

In an embodiment of the first aspect, the method further includes step A2), after step A1), of drying the first layer for at least 15 minutes at a predetermined temperature ranged from 40 to 70° C. to form a membrane layer.

In an embodiment of the first aspect, the method further includes step A3), after step A2), of further drying the membrane layer under vacuum condition to reduce the water content therein.

In an embodiment of the first aspect, the solution includes water-soluble synthetic polymer.

In an embodiment of the first aspect, the water-soluble synthetic polymer includes polyvinyl alcohol (PVA).

In an embodiment of the first aspect, the thickness of the first layer is manipulated by the concentration of the PVA solution and the relative rotation speed of the substrate.

In an embodiment of the first aspect, the concentration of the PVA solution is ranged from 3 wt % to 20 wt %.

In an embodiment of the first aspect, the deposition in step B) is performed by physical vapor deposition (PVD).

In an embodiment of the first aspect, the PVD includes at least one of magnetron sputtering and thermal evaporating.

In an embodiment of the first aspect, the temperature of the first layer is kept below 80° C. during step B), thereby preventing thermal induced physical property change of the first layer.

In an embodiment of the first aspect, step C) includes step C1) of immersing the first and second layers and the substrate into deionized water.

In accordance with the second aspect of the invention, there is provided a multilayer structure comprising: A) a substrate; B) a first layer arranged to deposit onto the substrate, wherein the substrate is rotatable relative to the depositing of the first layer; and C) a second layer arranged to deposit onto the first layer and separable from the first layer to form a nanosheet.

In an embodiment of the second aspect, the first layer is formed by depositing a solution onto the substrate during relative rotation between the depositing solution and the substrate.

In an embodiment of the second aspect, the second layer is separable from the first layer upon immersion of the multilayer structure in deionized water.

In an embodiment of the second aspect, the seperated second layer possesses an aspect (width-to-thickness) ratio ranging from 10⁵ to 10⁷.

In an embodiment of the second aspect, the first layer includes a PVA membrane.

In an embodiment of the second aspect, the second layer includes at least one of metallic and ceramic nanosheets.

In an embodiment of the second aspect, the metallic nanosheet is selected from pure metal, metallic glass and high entropy alloy, and the ceramic naonsheet is selected from ceramics and metal oxides.

In an embodiment of the second aspect, the pure metal includes Ti, the metallic glass includes ZrCuAlNi, the high entropy alloy includes FeCoNiCrNb, the ceramics is selected from amorphous-C and SiC, and the metal oxides include TiO₂.

In an embodiment of the second aspect, the thickness of the first layer is larger than the thickness of the second layer.

In an embodiment of the second aspect, the thickness of the first layer is equal to or larger than 500 nm.

In an embodiment of the second aspect, the thickness of the second layer is equal to or smaller than 150 nm.

### DETAILED DESCRIPTION OF THE PREFERRED EMBODIMENT

The inventors of the present invention have discovered that although certain types of nanosheets may be fabricate by existing synthesis methods, the expanding of the two-dimensional family is still severely impeded by the limited synthesis methods.

For instance, the fabrication of two dimensional metals mainly relies on a few wet-chemical methods, which are not capable of handling with most chemically complexed alloys such as the famous metallic glass and high entropy alloys. The fabrication of ceramic nanosheets is even more difficult. The production efficiency and cost are also affected by the relatively complex synthesis procedures and the environment requirement.

Without wishing to be bound by theories, the inventors have, through their own research, trials, and experiments, devised a low-cost facile approach for the massive production of large area metallic and ceramic nanosheets. The method disclosed in the present invention is capable of fabricating nanosheets of various metals, alloys and ceramics, such as Ti, ZrCuAlNi metallic glass, TiO₂ and SiC, which are formed by more complexed chemical structure.

By combining spin coating and PVD coating technologies, a spin coated layer may serve as interlayer with PVD coating technology serving as synthesis method, which is suitable for the massive production of nanosheets. The present invention takes advantage of the spin-coated first layer to facilitate the formation of nanosheets which is the second layer before peeling off. This enables the fabrication of large-area chemically complex nanosheets and such fabrication method may be applied to more materials with similar physical properties.

In addition to the enrichment of applicable material, these fabricated nanosheets may also have a macroscopic in-plane dimension, resulting in an extremely large aspect (width-to-thickness) ratio ranging from 10⁵ to 10⁷. As compared to other synthesis methods, the method disclosed in the present invention consists of a few economical simplified fabrication steps and showed the capability for massive production, meaning that this method could be readily adapted to real industrialization.

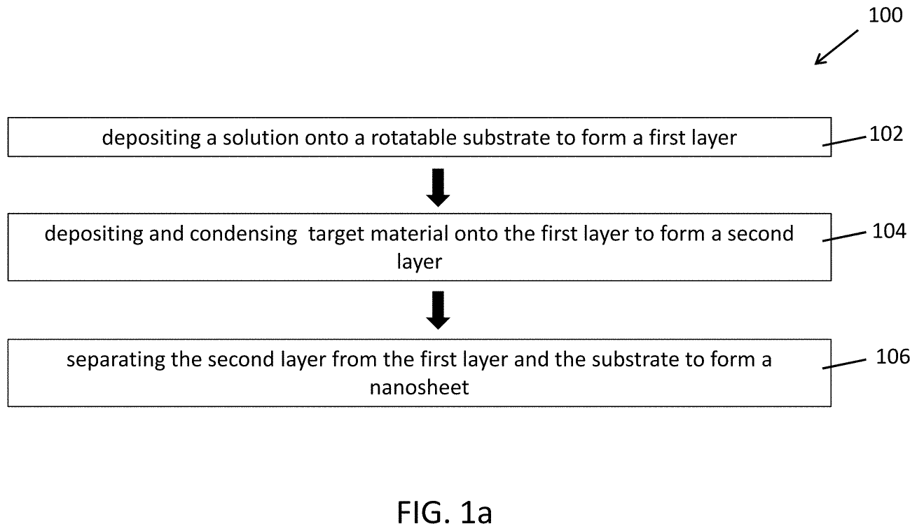

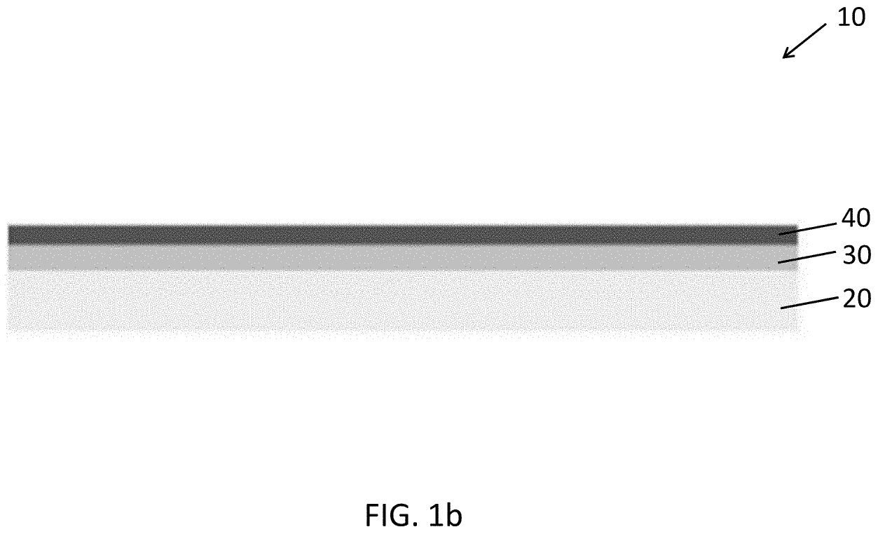

With reference to FIG. 1a, a block diagram is provided showing the process flow of a method 100 for preparing a nanosheet 40. The method comprises the steps of depositing a solution 32 onto a rotatable substrate 20 to form a first layer 30 in step 102; depositing and condensing target material 42 onto the first layer 30 to form a second layer 40 in step 104; and separating the second layer 40 from the first layer 30 and the substrate 20 to form a nanosheet in step 106.

Turning now to FIG. 1b for the detailed description of an exemplary multilayer structure 10 of the present invention. The multilayer structure 10 primarily includes a substrate 20, a first, lower layer 30 disposed onto the substrate 20, and a second, upper layer 40 disposed onto the lower layer 30. The lower layer 30 is an interlayer that is sandwiched between the substrate 20 and the upper layer 40 to form a film-PVA-substrate multilayer 10. The upper layer 40 is removable from the lower layer 30 for various applications such as adhering to or attaching to a target object 70 to provide desirable physical and/or chemical properties.

The substrate 20 may be an underlying layer for depositing one or more additional layers thereon. The substrate 20 is preferably a plane surface for receiving non-sticky liquid. The substrate 20 is preferably a glass slide for illustrative purpose. The substrate 20 may also be a silicon (Si) wafer.

The lower layer 30 is formed by a water-soluble synthetic polymer and preferably formed by a layer of Polyvinyl alcohol (PVA). PVA is colorless and highly soluble in water whilst insoluble in most of the organic solvents. More specifically, the PVA layer 30 is in the form of a membrane that is sufficient to hold the target material deposited thereon and remains inactive during the formation of the upper layer 40 and separation of the upper layer 40 from the multilayer structure 10.

The upper layer 40 is a nanosheet which possesses two-dimensional nanostructure with a minimal thickness at nanoscale. The nanosheet 40 may be a thin film with macroscopic in-plane dimension i.e. large aspect (width-to-thickness) ratio. Preferably, the nanosheet 40 to be fabricated by the present invention includes large-area chemically complex e.g. metallic and ceramic nanosheet. For instance, the metallic nanosheet 40 may be pure metal e.g. pure Ti, metallic glass e.g. ZrCuAlNi, high entropy alloy that composed of five or more elements with near equi-atomic ratio and without principal/dominant element e.g. FeCoNiCrNb. On the other hand, the ceramic nanosheet 40 may be ceramics e.g. amorphous-C or SiC or metal oxides e.g. TiO₂.

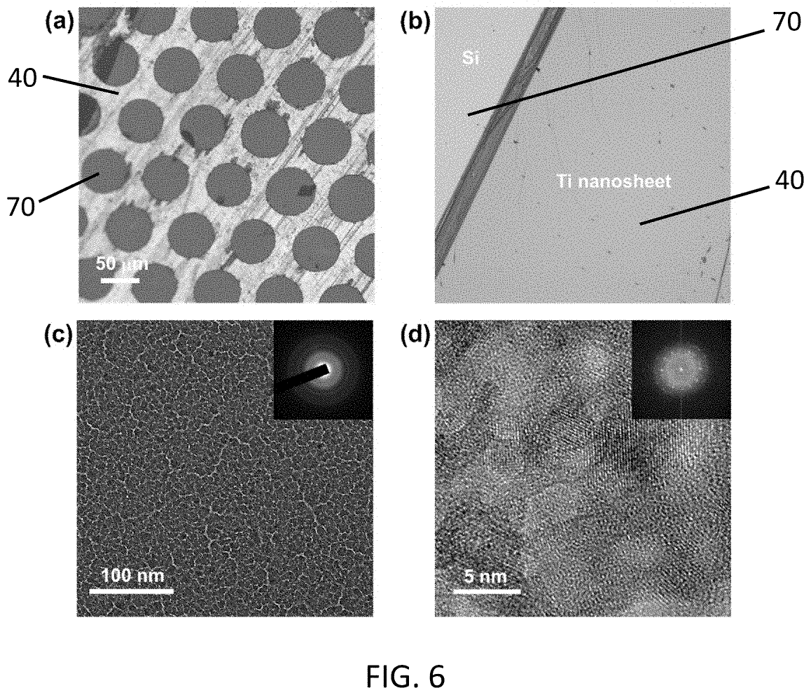

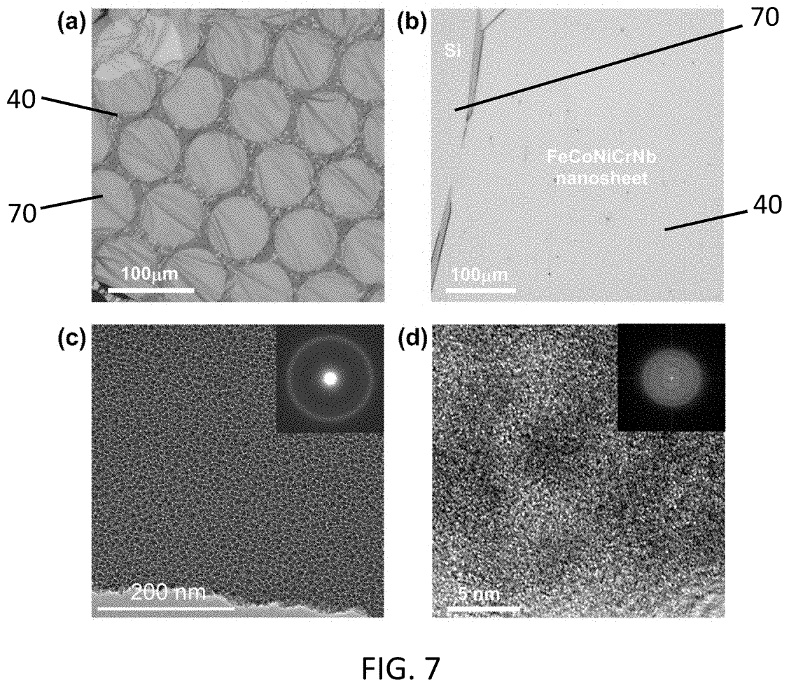

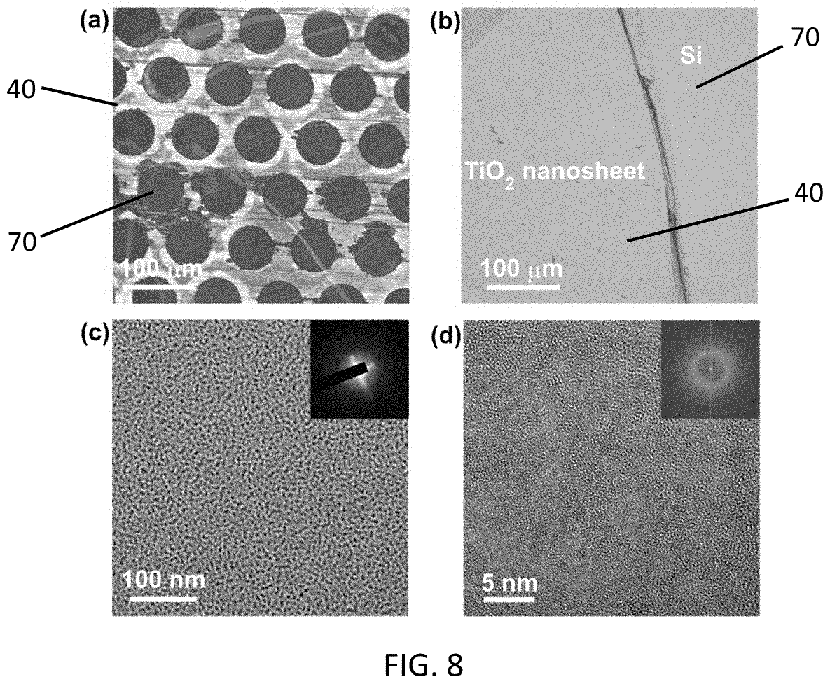

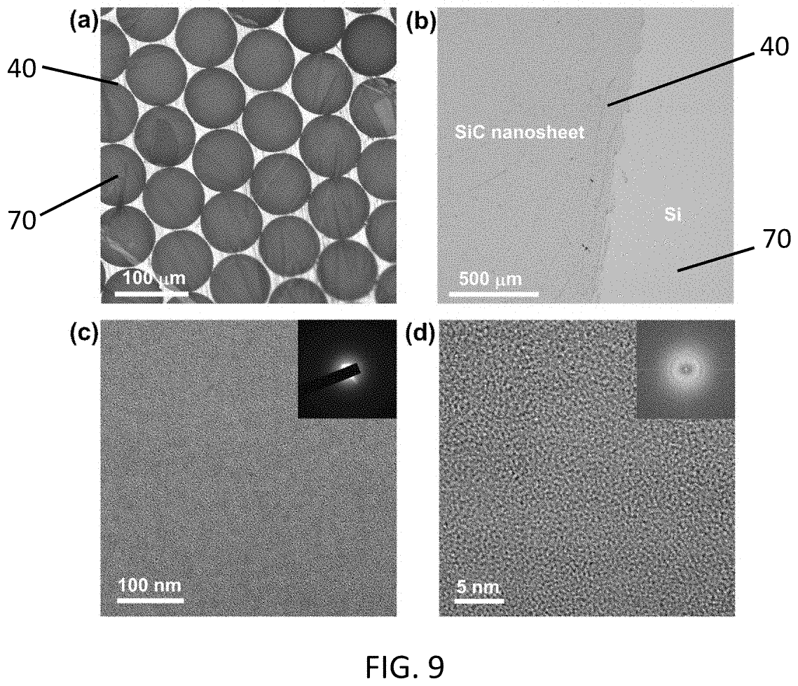

The nanosheet 40 may be formed through a massive fabrication. The large two-dimensional, nanosheet 40 may then be applied onto the target object 70 such as copper grid (as shown in FIGS. 6a, 7a, 8a and 9a) or Si wafer (as shown in FIGS. 6b, 7b, 8b and 9b) afterwards. Thus, the nanosheet 40 may cover various types of materials and has high practicability in a wide range of applications.

To prepare the lower PVA layer 30, PVA powder is first dissolved into deionized water and mixed to form a PVA solution 32 with a predetermined concentration. The substrate 20 is rest upon a rotatable disc 12 that is rotatable about a rotating axis. When the rotation of the rotatable disc 12 is actuated, the PVA solution 32 is introduced from a sprayer head 34 and deposited onto the substrate 20 such that the PVA solution 32, by centrifugal force exerted onto the substrate 20 through spinning, may uniformly distribute and cover the upper surface of the substrate 20 to form the PVA layer 30.

Advantageously, the nature of the spin coating technique ensures the high quality of the PVA membrane 30 and is thus suitable for industrialized massive production. Alternatively, the sprayer head 34, instead of the substrate 20, may be rotatable relative to the substrate 20 or the sprayer head 34 may be rotatable in addition to the rotational movement of the rotatable disc 12.

On the other hand, to prepare the nanosheet 40, the substrate 20 spin coated with PVA layer 30 i.e. PVA-substrate double layer may serve as substrate for physical vapor deposition and subsequently, an additional layer is coated thereon to form the multilayer structure 10. In particular, atoms or material clusters from a solid source e.g. sputtering target 44 is first ejected, for instance by sputtering gas typically an inert gas such as argon and then the resulting atoms or clusters 42 are deposited onto the PVA layer 30 and condensed thereon to form a film-PVA-substrate multilayer structure 10. During deposition, the solid 44 goes from a condensed phase to a vapor phase and then back to a thin film condensed phase.

Lastly, the multilayer structure 10 is immersed in a container 50 filled by deionized water 52 and the film 40 is in turn removed from the multilayer structure 10 to form the nanosheet 40. Throughout the entire process, the spin coated PVA membrane 30 serves as an interlayer to fabricate metallic and ceramic nanosheets 40.

In one example embodiment, the method for the fabrication of metallic and ceramic nanosheets contains the following steps: preparing a layer of Polyvinyl alcohol (PVA) 30 on a proper substrate 20, applying target thin films 40 on the prepared PVA surface 30, and peeling off of the target thin film 40.

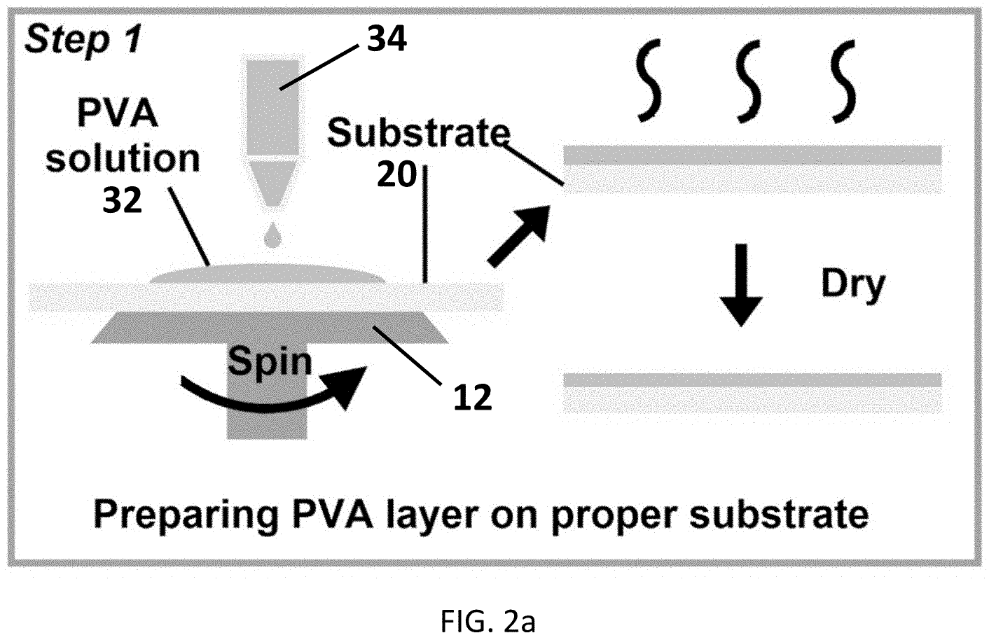

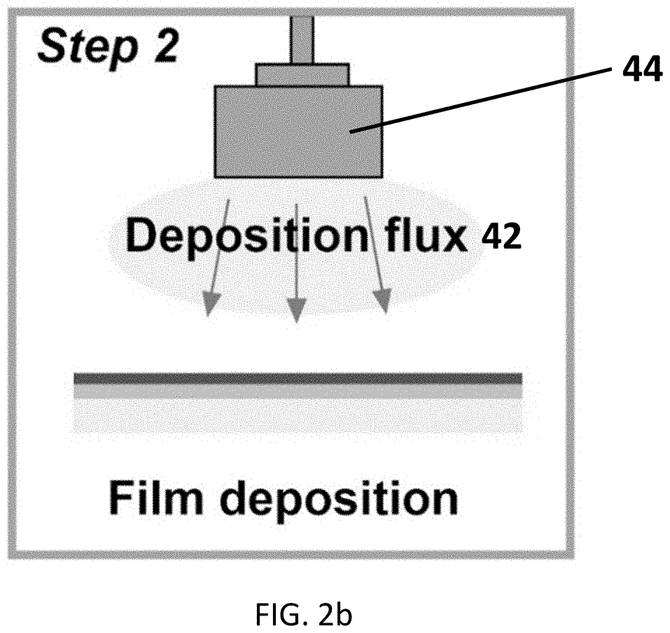

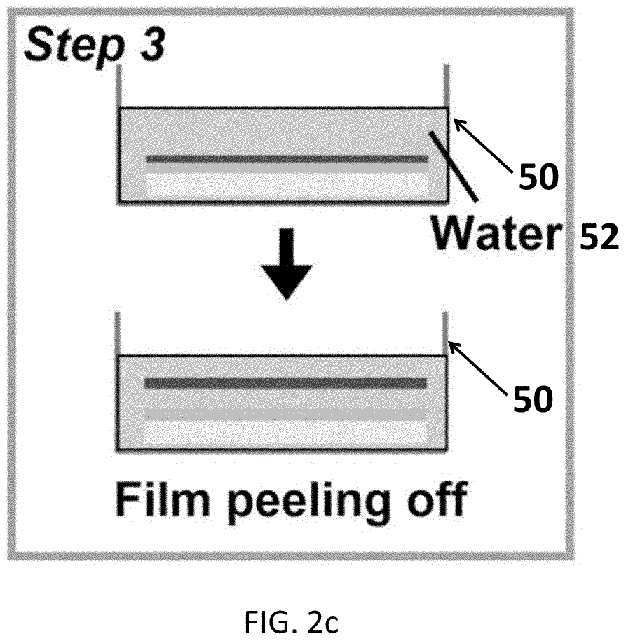

Referring to FIG. 2a for the first step of preparing a layer 30 of Polyvinyl alcohol (PVA) on the substrate 20. Proper substrate 20 such as glass slides with a lateral size of 100 mm*100 mm may be chosen. PVA powder such as 0588-type commercial PVA powder is mixed with deionized water to prepare PVA solution 32 with proper concentration ranging from 3 wt % to 20 wt %. The PVA solution 32 is spin coated as a layer of PVA gel evenly on the substrate 20. The spinning speed is ranged from 1 k rpm to 8 k rpm depending on the PVA concentration. The PVA layer 30 is subsequently dried in a drying oven for at least 15 minutes with oven temperature of 40 to 70° C. The dried PVA gel forms a layer of PVA membrane 30 on the substrate 20.

Additionally, the dried PVA membrane 30 together with the substrate 20 are put into vacuum chamber for at least 4 hours to further diminish the water content in the membrane 30. The thickness of the PVA membrane 30 should be kept larger than 500 nm. Preferably, the thickness can be controlled by adjusting the PVA concentration and the spin coating speed respectively. For example, the higher the concentration of the PVA solution, the larger the thickness of the PVA layer 30. In contrast, the higher the spin coating speed, the smaller the thickness of the PVA layer 30.

Turning now to FIG. 2b for the second step of applying target thin films 40 on the prepared PVA surface 30. To apply a thin films 40 on the as-prepared PVA membranes 30, several kinds of physical vapor disposition (PVD) methods such as magnetron sputtering, thermal evaporating etc. are suitable for depositing the thin film 40 onto the PVA membrane 30. During the deposition, the temperature of the PVA membrane 30 is kept lower than 80° C. to avoid thermal induced physical property change of the PVA membrane 30. By using one of the physical vapor disposition methods, the thickness of the applied thin film 40 would be manipulated and would not exceed 150 nm. This ensures that the thin film 40 may be peeled off from the PVA membrane 30 without experiencing difficulties. Subsequently, the film-PVA-substrate system may proceed to the peeling off stage.

Alternatively, the film-PVA-substrate multilayer 10 may be transferred into vacuum chamber immediately for storage to avoid exposure in humid air. The stored film-PVA-substrate multilayer 10 may be transported to another site and further processed at a later stage.

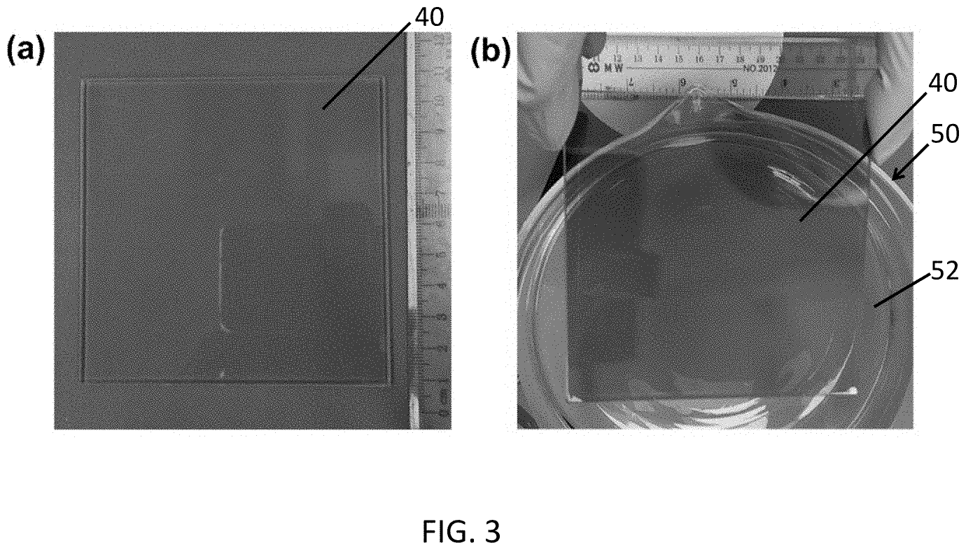

Turning now to FIG. 2c for the final steps of peeling off of the target thin film 40. The film-PVA-substrate system 10 may be immersed in deionized water (as shown in FIG. 3b). During the immersion, the coated surface is kept facing upward and avoids severe water flow in the water environment. The peeling off process generally would take a few hours to complete.

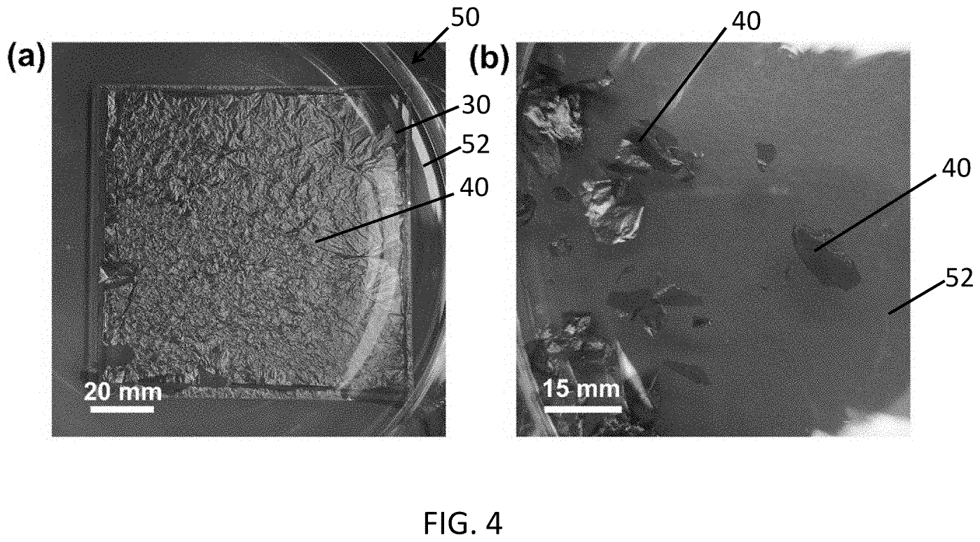

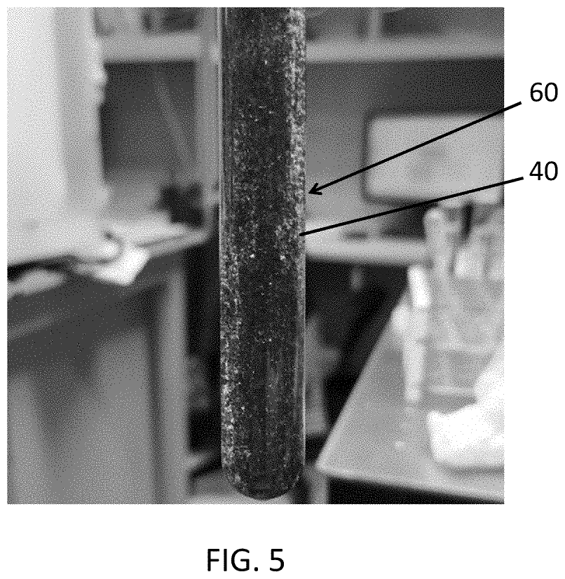

In one example embodiment, Ti nanosheet 40 is formed on a PVA-glass slide as shown in FIG. 3a and is immersed in a deionized water as shown in FIG. 3b for a period. The Ti nanosheet 40 is thus exfoliated during immersion (as shown in FIG. 4a) and subsequently would peel off from the glass slide (as shown in FIG. 4b). FIG. 5 illustrates a test tube 60 filled with Ti nanosheet 40 collected from four glass slides 20.

In yet another example embodiment, FeCoNiCrNb nanosheet, TiO₂ nanosheet and SiC nanosheet may also be formed by similar fabricating procedures as aforementioned. Ti nanosheet, FeCoNiCrNb nanosheet, TiO₂ nanosheet and SiC nanosheet may be securely transferred onto 300-mesh copper grid or Si wafer 70, each of which are depicted in FIGS. 6a to 6b, 7a to 7b, 8a to 8b, and 9a to 9b respectively.

The respective TEM images (with the inset showing the corresponding diffraction pattern) and the HRTEM images (with the inset showing the corresponding fast Fourier transform image, FFT) are also depicted in FIGS. 6c to 6d, 7c to 7d, 8c to 8d, and 9c to 9d respectively to show the inner structure of the nanosheet 40, in which the atoms are properly aligned and tightly packed with each other.

Some technical advantages of the embodiments of the present invention include:
The resulted nanosheets 40 have ultra-large area, larger than most of the nanosheets that can be fabricated using the existing wet-chemical methods;
The present method is capable of fabricating chemically complex metals and even ceramics, which is not possible for the existing technique;
The fabrication process contains only a few simple steps and further reduced the consumption of PVA, which reduces the fabricating cost. Therefore, the present method may be adapted for industrial massive production;
PVA is a non-toxic material and thus the present method is very safe and environment-friendly.

Embodiments of the present invention can be applied to various applications and fields, for example:
Chemical catalyst

There are lots of potential applications, which depend on the physical and chemical properties of the material. Owing to the large aspect ratio and surface area, the fabricated nanosheets are ideal candidate catalyst in various kinds of chemical reactions. For example, the TiO₂ nanosheets could be used as photocatalyst in dye degradation.
Surface engineering and Semi-conductor market

The capability of fabricating large area free-standing ceramic nanosheets makes it possible to apply circuit structures on the ceramic layers to form ultra-thin wearable electronic devices.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

Any reference to prior art contained herein is not to be taken as an admission that the information is common general knowledge, unless otherwise indicated.

1. A method for preparing a nanosheet comprising the steps of:
A) depositing a solution onto a substrate to form a first layer, wherein the substrate is rotatable relative to the depositing solution;
B) depositing and condensing target material onto the first layer to form a second layer; and
C) separating the second layer from the first layer and the substrate to form a nanosheet.

2. The method according to claim 1, wherein step A) includes spin-coating the solution uniformly onto the substrate to form the first layer.

3. The method according to claim 2, wherein step A) includes step A1) of rotating the substrate relative to the depositing solution, thereby uniformly distributing the solution onto the substrate.

4. The method according to claim 3, further including step A2), after step A1), of drying the first layer for at least 15 minutes at a predetermined temperature ranged from 40 to 70° C. to form a membrane layer.

5. The method according to claim 4, further including step A3), after step A2), of further drying the membrane layer under vacuum condition to reduce the water content therein.

6. The method according to claim 1, wherein the solution includes water-soluble synthetic polymer.

7. The method according to claim 6, wherein the water-soluble synthetic polymer includes polyvinyl alcohol (PVA).

8. The method according to claim 7, wherein the thickness of the first layer is manipulated by the concentration of the PVA solution and the relative rotation speed of the substrate.

9. The method according to claim 8, wherein the concentration of the PVA solution is ranged from 3 wt % to 20 wt %.

10. The method according to claim 1, wherein the deposition in step B) is performed by physical vapor deposition (PVD).

11. The method according to claim 10, wherein the PVD includes at least one of magnetron sputtering and thermal evaporating.

12. The method according to claim 11, wherein the temperature of the first layer is kept below 80° C. during step B), thereby preventing thermal induced physical property change of the first layer.

13. The method according to claim 1, wherein step C) includes step C1) of immersing the first and second layers and the substrate into deionized water.

14. A multilayer structure comprising:
A) a substrate;
B) a first layer arranged to deposit onto the substrate, wherein the substrate is rotatable relative to the depositing of the first layer; and
C) a second layer arranged to deposit onto the first layer and separable from the first layer to form a nanosheet.

15. The multilayer structure according to claim 14, wherein the first layer is formed by depositing a solution onto the substrate during relative rotation between the depositing solution and the substrate.

16. The multilayer structure according to claim 14, wherein the second layer is separable from the first layer upon immersion of the multilayer structure in deionized water.

17. The multilayer structure according to claim 14, wherein the seperated second layer possesses an aspect (width-to-thickness) ratio ranging from 10⁵ to 10⁷.

18. The multilayer structure according to claim 14, wherein the first layer includes a PVA membrane.

19. The multilayer structure according to claim 14, wherein the second layer includes at least one of metallic and ceramic nanosheets.

20. The multilayer structure according to claim 19, wherein the metallic nanosheet is selected from pure metal, metallic glass and high entropy alloy, and the ceramic naonsheet is selected from ceramics and metal oxides.

21. The multilayer structure according to claim 20, wherein the pure metal includes Ti, the metallic glass includes ZrCuAlNi, the high entropy alloy includes FeCoNiCrNb, the ceramics is selected from amorphous-C and SiC, and the metal oxides include TiO₂

22. The multilayer structure according to claim 14, wherein the thickness of the first layer is larger than the thickness of the second layer.

23. The multilayer structure according to claim 22, wherein the thickness of the first layer is equal to or larger than 500 nm.

24. The multilayer structure according to claim 22, wherein the thickness of the second layer is equal to or smaller than 150 nm.
